(19) United States
(12) Patent Application Publication
(10) Pub. No.: US 2003/0109994 A1
(43) Pub. Date: Jun. 12, 2003

(54) Charger system for receiving and transferring data to an electronic device

(75) Inventors: Thomas James Dubil, Morgan Hill, CA (US); Stuart Peter McKechnie, San Jose, CA (US)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/020,022

(22) Filed: Dec. 6, 2001

(51) Int. Cl. G06F 19/00; G01R 31/36

(52) U.S. Cl. 702/63

(57) ABSTRACT

A charging system is provided for receiving data from a remote source and transferring the data to an electronic device. The charging system includes a charger including a coupling connector for coupling to a rechargeable electronic device, wherein the coupling connector includes charging circuitry for providing an electrical charge to the rechargeable electronic device and a communication port for transferring data to the rechargeable electronic device. The charging system further includes a network connection for receiving the data from a remote source and selectably transferring the data upon receipt to at least one of the communication port and a storage means of the charger. In one embodiment the rechargeable electronic device is a remote control device for controlling a television, and the data is a television channel guide.

### BACKGROUND OF THE INVENTION

1. Technical Field

The present disclosure relates generally to a charger system for an electronic device, and in particular to a charger system for receiving and transferring data to an electronic device.

2. Background of the Related Art

Several electronic devices exist which have the ability to receive data via wireless or non-wireless means. A remote control device displaying a television channel guide is an example of an electronic device that can receive data via a hard-wired connection or wireless connection to a set-top box. The received data is generally an updated television channel guide. The ability to receive and display the television channel guide by the remote control device foregoes the need for a user to flip through the various channels for determining the programs currently being aired and/or scheduled to air. The remote control device can also be used to select a desired program from the displayed television channel guide if the display is a touch-screen display.

The television channel guide is provided as data to the remote control device via the hard-wired or wireless connection. The updated television channel guide is received by the remote control device by various means, such as an RF link (wireless) or a direct connection to an Internet-connected host (non-wireless), such as a set-top box or a personal computer; an RF link to a remote central station which broadcasts an RF modulated signal which includes the television channel guide; or via an infrared signal from a set-top box receiving a broadcast signal which includes the television channel guide.

U.S. Pat. No. 5,689,825, Averbuch et al., entitled “Method and Apparatus for Downloading Updated Software to Portable Wireless Communication Units” describes a portable wireless communication unit coupled to a battery charger/software downloader via a unit interface. However, among other things, this patent does not describe selective downloading of data received by the charger to at least one of storage means and the portable unit.

It is envisioned to provide a rechargeable electronic device, such as a rechargeable remote control device, having the ability to receive data, such as a television channel guide, via a charger.

### SUMMARY OF THE INVENTION

Therefore, it is an object of the present invention to provide a charger system having at least a charger and a rechargeable electronic device capable of being recharged by the charger and of receiving data via the charger.

Accordingly, the present disclosure provides a charging for receiving data from a remote source and transferring the data to an electronic device. The charging system includes a charger including a coupling connector for coupling to a rechargeable electronic device, wherein the coupling connector includes charging circuitry for providing an electrical charge to the rechargeable electronic device and a communication port for transferring data to the rechargeable electronic device. The charging system further includes a network connection for receiving the data from a remote source and selectably transferring the data upon receipt to at least one of the communication port and a storage means of the charger. In one embodiment the rechargeable electronic device is a remote control device for controlling a television, and the data is a television channel guide.

### BRIEF DESCRIPTION OF THE DRAWINGS

The invention is further explained by way of example and with reference to the accompanying drawings, wherein:

FIG. 1 is a block diagram of a charger system for providing data to a rechargeable electronic device via a charger device in accordance with the present invention;

FIG. 2 is a block diagram of the rechargeable electronic device connected to the charger device of FIG. 1;

FIG. 3 is a perspective view of the charger device in accordance with the present invention;

FIG. 4A is a perspective top view of the rechargeable electronic device in accordance with the present invention; and

FIG. 4B is a perspective bottom view of the rechargeable electronic device in accordance with the present invention.

### DETAILED DESCRIPTION OF PREFERRED EMBODIMENTS

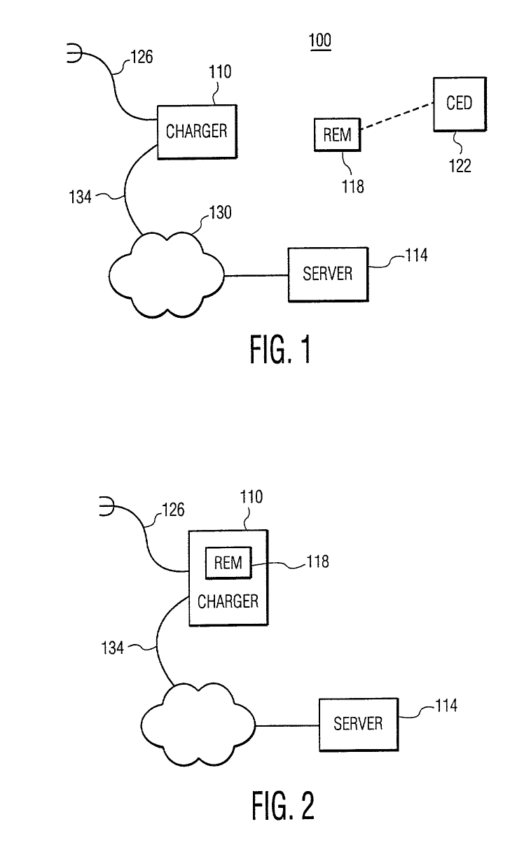

FIGS. 1 and 2 show an exemplary charger system 100 for downloading data to a charger 110 from a server 114 and transferring the data to a rechargeable electronic device 118 when the rechargeable electronic device 118 is placed within a cradle of the charger 110. In the example shown, the rechargeable electronic device 118 is a remote control device for controlling a consumer electronic device (CED) 122, such as a television. In FIG. 1 the rechargeable electronic device 118 is shown to be in an operative position or non-charging mode. In this mode, the device 118 is disconnected and removed from the charger 110 and usable for sending RF signals to the CED 122 for controlling the CED 122. FIG. 2 shows the rechargeable electronic device 118 in a charging mode in which the rechargeable electronic device 118 is connected to the charger 110 for recharging a rechargeable battery within the rechargeable electronic device 118.

As shown in FIGS. 1 and 2, the charger 110 includes an electrical cord 126 for connecting to a power supply, such as a wall outlet. The charger 110 can also be powered by a battery. The charger 110 is shown to be in communication with the server 114 via a network 130. The network 130 is any network providing communication between two or more computers, such as the Internet. The charger 110 communicates with the network 130 by wired or wireless means, as is known in the art. For example, the charger 110 is provided with a modem for connecting via a PSTN network to the Internet. The charger 110 also includes wireless communication software and/or hardware for wirelessly connecting to the network 130. The network 130 and the server 114 may be land-based, non-land based or a combination thereof. The charger 110 may be in communication with one or more servers 114. The server 114 may further be in communication with one or more other servers 114.

The server 114 includes hardware and software for facilitating communication with the network 130. Preferably, the server 114 is a web server having standard hardware and software components for handling user requests from an Internet connected charger 110, processing the requests, and transmitting requested files, i.e., data, to the charger 110 upon receipt of a request. Alternatively, it is possible for the server 114 to be in direct communication with the charger 110, without an intervening network 130, where the server 114 receives, processes and responds to requests from the charger 110. In another embodiment, the server 114 provides files, i.e., data to the charger 110 upon the occurrence of an event, such as a time-based event. Where the rechargeable electronic device 118 controls a television, the data received by the charger 110 is a television channel guide for display by the rechargeable electronic device 118.

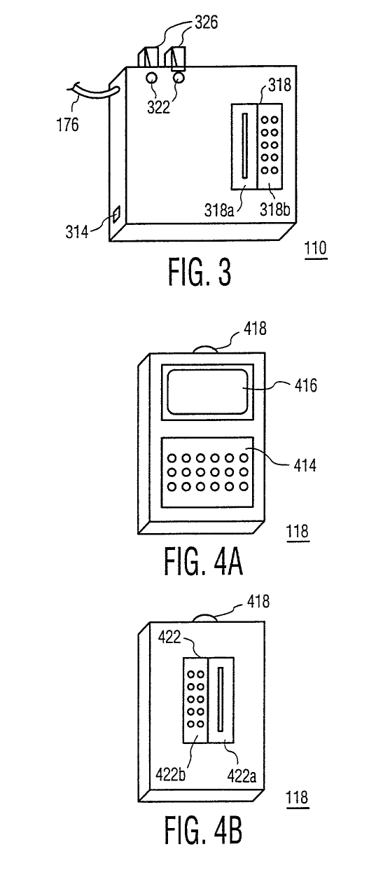

FIG. 3 shows the charger 110 including the electrical cord 126, a network communication means 314, a rechargeable electronic device connector 318, indicator lights 322 and activation switches 326. The network communication means 314 can be any standard connection mechanism for connecting to a network. The rechargeable electronic device connector 318 includes a standard charging connector 318a for transferring electrical power to the rechargeable electronic device 118 for recharging the device 118. The connector 318 also includes a standard data communication port 318b for transmitting and receiving data, e.g., an RS-232 data port. The indicator lights 322 include one or more indicator lights for indicating various functions, such as power on/off, charging of the rechargeable electronic device 118, receipt of data via the network, transfer of data between the charger 110 and the rechargeable electronic device 118, etc.

The charger 110 further includes a processor, memory, and a conventional charging unit for providing electrical power from the cord 126 to the charging connector 318a for charging the rechargeable electronic device 118. The processor may include one or more processing devices, such as a microprocessor or a digital signal processor (DSP), and executes procedures necessary for processing requests from the rechargeable electronic device 118, establishing communication with the server 114, transmitting the requests to the server 114, processing data received from the server 114, and providing the received data to the electronic device 118 via the data communication port 318b. Preferably, the processor uses a standard web browser program to access the server 114 via the Internet. The processor also includes an internal clock for determining when to initiate a time-based event.

FIGS. 4A and 4B show top and bottom perspective views, respectively, of the rechargeable electronic device 118. It is understood by one skilled in the art that the rechargeable electronic device 118 is any rechargeable device capable of receiving and processing the updated or received data, i.e., any consumer electronic device. The disclosure herein, however, is not limited to a consumer environment.

With reference to FIG. 4A, the rechargeable electronic device 118, is shown as a remote control device 118 for controlling a television. The device 118 may also be a device capable of functioning as a remote control device, such as handheld personal computer functioning as a remote control device. The device 118 includes a display 410 for displaying the updated data, such as a television channel guide. The remote control device 118 is preferably designed as a universal remote control device for controlling a home entertainment system, which includes a television. The television, as known in the art, has multiple functionalities that are user-controllable by the remote control device 118, e.g., “TV_on/off”, “channel up/down”, “mute”, “brightness up”, etc.

The remote control device 118 further includes a user interface 414 with multiple user inputs (e.g., buttons, soft keys on a GUI, or a microphone for voice inputs). The multiple user inputs provide selective control of a particular one of the multiple functionalities of the television or any other apparatus of the home entertainment system by sending a particular one of multiple control signals via an RF transmitter 418. The remote control device 118 of the embodiment of FIG. 4A further includes means for providing output to the user, such as a GUI 416 for providing video output, and a speaker for providing audio output.

The remote control device 118 further includes a processor, memory, a rechargeable battery, and a recharging unit for providing electrical power to the rechargeable battery for recharging thereof. The processor may include one or more processing devices, such as a microprocessor or a digital signal processor (DSP), and executes procedures necessary for transmitting requests to the charger 110, processing data received from the charger 110, processing user inputs from user interface 414 and providing output data to the GUI 416 for display.

With reference to FIG. 4B, the remote control device 118 further includes a charger connector 422 including a standard mating charging connector 422a for mating with the charging connector 318a of the charger 110 for transferring power from the charger 110 to the remote control device 118. The charger connector 422 further includes a standard mating data communication port 422b, such as an RS-232 port, for mating with the data communication port 318b of the charger 110 for transmitting and receiving data therefrom.

In the example provided, in which the rechargeable electronic device is the remote control device 118 controlling a television, the data being downloaded to the charger includes, for example, at least one of a) the television channel guide (graphic or audio); b) messages (text, graphic or audio); c) commands for execution by the processor of the remote; and d) commands for execution by the processor of the charger 110. The data, such as the television channel guide and messages, may be provided as an XML document, and may include an XSL style sheet. An XML application at the receiving end is used, for example, for control of generating the proper IR or RF commands based on the received data and for generating a GUI as an, e.g., HTML page on a suitable display.

The XML data can also contain control codes associated with the content in order to enable user interaction with a remote device, such as the television or a video cassette recorder, for channel navigation, content recording, etc. The XML data may also contain a Java applet, i.e., a script, e.g., JScript, JavaScript, and VBScript, to provide greater flexibility for GUI presentation and device control. In a home networking environment, e.g., UPnP, HAVi, Jini and others, the remote control device 118 can act as a control point for a set top box, television, recording equipment and other network devices. The XML data can also contain data relating to current or future content available through the television or other device.

Data that includes executable commands may contain commands for the charger 110 to execute for downloading future data, including a URL of a server and a time for scheduling a request or a series of requests for a download. The server 114 may monitor data traffic and provide the charger 110 with optimal times for scheduling download requests at which data traffic is minimal. Data including executable commands may further contain commands for the updating or patching of software currently stored for execution by one of the charger 110 or the remote control device 118.

Operation of the downloading of updated data from the server 114 to the charger 110 will now be described. In a first embodiment, the charger 110 is programmed to initiate a request to the server 114 for updated data in accordance with the occurrence of an event, such as a time-based event (i.e. the internal clock of the charger's 110 processor matches a stored scheduling time) or user request, such as by activation of an activation switch 326. Upon the occurrence of an event, the charger 110 is programmed to establish communication with the network 130, such as the Internet (a permanent Internet connection may be provided), and the charger's web browser establishes communication with the server 114 by supplying the web browser with the URL corresponding to the server 114 being contacted. As noted above, the charger 110 may be capable of communicating with more than one server 114.

A subscriber using the charger 110 subscribes to the service provided by the server 114 by providing payment, if required, and registering the charger with the server 114, such as by using a personal computer to electronically register via a web site provided by the server 114, or by using conventional mail or telephone to provide registration data to operators for processing the registration. During registration, registration data relating to the charger 110 and/or subscriber are provided to the server 114, allowing the server 114 to use the information for providing customized service and different levels of service.

The request initiated by the charger 110 contains identifying information identifying the charger 110, and request data indicating the nature of the request. The request may further contain the URL of the charger 110.

Upon receipt of the request by the server 114, the server 114 recognizes the identity of the charger 114 and either looks up in a table of stored registration data the URL of the charger 110 that transmitted the request, or retrieves the URL of the charger 110 from the request. The server 114 selects data to be provided to the charger 110 in accordance with the registration data and the request data. Preferably, the data is accompanied by an identifier identifying the type of the data, such as executable commands, look-up table, television channel guide, message, etc. The identifier may further identify a data subtype for further identifying the data.

Examples of subtypes for the different types of data include: for an executable program, a particular subroutine; for the television channel guide, a particular channel or a particular time slot; and for a message, status of an update or an emergency message. The identifier may be embedded in the data or attached to the data, such as in a header. The server 114 transmits the data to the URL of the charger 110 submitting the request. The server 114 is responsible for updating the data and maintaining the data to be updated. The server 114 may obtain the data, portions of the data or obtain updates to the data from other servers 114 or PCs.

The charger 110 receives the data transmitted by the server 114 and determines the data type and subtype. The processor of the charger 110 stores the received data in a location specified for the data in accordance with the data type and subtype. The processor of the charger 110, may further trigger activation of an indicator 322, indicating that a new data update has been received. Indication may further be provided of the data type of the new data update. The charger's processor is programmed to either replace previously stored data with the received data or to add the received data to the data previously stored, i.e., append the previously stored data with the receiver data, in accordance with the data type and/or user preference. For example, only the latest version of the television channel guide may be stored, where each update to the television channel guide received replaces previously stored data. In another example, each public emergency message may be stored, where the received message update is stored in addition to the previously stored data.

As previously noted, the charger 110 is programmed to initiate a request for a data update and to store received data in accordance with the type and/or subtype of the data and/or user preference. Programming of the charger 110 for the above functions, as well as other functions may be performed at the time of manufacture, such as by providing default times and URL's, i.e., default parameters or settings, for update requests and data storage instructions. It is possible to re-program the charger 110, i.e., to change the default settings.

Preferably the charger 110 is programmed to automatically generate a transfer request signal in accordance with the occurrence of an event, which can be overridden or disabled by using an activation switch 326 on the charger 110 or using a switch on the remote control device 118 while it is coupled to the charger 110. The transfer request signal may be triggered via user operation of the charger device, such as by activating an activation switch 326, or by user input to the remote control device 118, such as via the user interface 414.

In one embodiment, the charger 110 is programmable by the server 114, where the server 114 sends updated executable commands for changing the default parameters. Thus, the server 114 may determine the best times for a data update request by determining best times during which data downloads should be performed, such as by determining the times when data lines have the least data traffic. Furthermore, the server 114 may stagger download requests by programming subscribing chargers 110 to initiate data update requests at staggered times. The server 114 may further direct requests to other URLs.

In another embodiment, the charger 110 is programmable by the user of the remote control device 118, where the user enters information using the user interface 414 and GUI 416 on the remote control device 118 and/or by the user of the charger 110 via a user interface and GUI or audio interface provided on the charger 110. The user is provided with access to the programmable parameters, such as by a menu or series of menus, and the user enters the desired values.

In another embodiment, the download of data from the server 114 to the charger 110 is initiated by the server 114 in accordance with an event such as a time-based event, a data update event or an action by an operator of the server 114. For example, the server 114 may download an updated television channel guide to all subscribing chargers 110 at a predetermined time each week. In another example, the server 114 may transmit to subscribing charger's 110 an updated television channel guide schedule for late Monday PM through early Tuesday AM on a Monday night at 10:30 P.M, upon the event of a scheduled football game on Monday night running longer than originally scheduled.

In order not to miss data updates and to avoid unnecessary data transmissions, subscribing chargers 110 receiving server 114 initiated downloads are either continually available for receiving downloads, or provide the server 114 with notification as to when they are not available and when they are available for receiving downloads. The server 114 tracks successful transmission of updated data as well as unsuccessful transmissions and missed transmissions due to a charger 110 being not available for receiving downloads. The server 114 stores data that was not successfully downloaded to corresponding chargers 110. The server 114 may be operated or programmed to delete data that is outdated, such as due to newer updates or a lapse of a predetermined time period. Unsuccessful transmissions may be investigated for determining the problem and the data may be retransmitted. Upon a charger 110 becoming available after a period of unavailability, pertinent missed downloads are downloaded to the charger 110.

Transfer of the updated data received by the charger 110 to the remote control device 118 will now be discussed. The transfer of the data from the charger 110 to the remote control device 118 may be performed in a direct mode or an indirect mode. In the direct mode the received data is transferred directly to the data communication port 318b for transfer to the remote control device 118. In the indirect mode the received data is transferred to the charger's memory. The charger 110 may operate in exclusively the direct mode or the indirect mode, or the mode may be selectable by the user, such as via an activation switch 326 on the charger 110 or the user interface 414 on the remote control device; by the server via parameters associated with the downloaded data; or automatically. For example, upon user initiation of a request for a download of data from the server 114, the direct mode would be automatically selected for direct transfer of the downloaded data to the remote control device 118.

A transfer request signal is sent to the charger 110 to transfer the newly updated data or new data stored by the charger 110 either automatically upon the remote control device 118 being engaged with the charger 110 for charging or by user request, such as via one of activation of an activation switch 326 of the charger or of the remote control device 118, or a user action via the user interface 414 of the remote control device 118. The transfer request signal may indicate the type of data, i.e., executable commands, look-up table, television guide, message, etc., that a transfer is being requested for.

In addition, if the remote control device 118 is engaged with the charger 110 for recharging when a new data update is downloaded to the charger 110, upon completion of the download to the charger 110, the charger 110 or the remote control device 118 may detect the completion of the download and initiate a request to transfer the newly downloaded data to the remote control device 118. The charger's processor receives the transfer request signal and prepares to transfer stored data. It is contemplated that the data is simultaneously transferred to the remote control device 118 while the remote control device 118 is being recharged.

The data is transferred through the charger's data communication port 318b to the remote control device's data communication port 422b. Upon successful transfer of the data, the charger 110 may either delete the data that was transmitted or set an associated sent flag indicating that the data was already transmitted to the remote control device 118. Thus, the charger 110 may save one or more older versions of data that was transferred.

Upon successful transfer of the data to the remote control device 118, the remote control device 118 determines the type and, if provided, the subtype provided in the identifier associated with the data. The remote control device 118 stores the transferred data in its memory in a place that corresponds to the data type and subtype. The remote control device 118 stores a previous version of the data in a different location in its memory prior to receiving the transmitted data. Alternatively, the remote control device 118 deletes the oldest version of the data to free-up memory.

In another embodiment, two or more remote control devices 118 are associated with the charger 110 for receiving updated data through the charger 110. When sending a transfer request signal from one of the two or more remote control devices 118 to the charger 110, an identification code identifying the remote control device 118 also sent to the charger 110. The charger's processor tracks which updates have been sent to each remote control device 118 of the two or more remote control devices 118. An old flag having an associated remote control device 118 identification code may be associated with stored data that was already transferred to one of the two or more remote control devices 118.

It is contemplated that an identification (ID) data code is associated with each data unit stored in the remote control device 118 that is available for update via data transfer from the charger 110. The charger 110 requests the ID code of a correlating data unit stored by the remote control device 118 and compares it with the ID code of a new available update. If the data update available from the charger 110 is different than the data stored by the remote control device 118, then the data update is transferred from the charger 110 to the remote control device 118 and the data stored by the remote control device 118 is replaced by the data update. It is further contemplated that the server 114 compares available updates with data already stored by the charger 110 prior to downloading the data to the charger 110.

It is further contemplated that the remote control device 118 is functional while charging and while receiving data from the charger 110 for operating the server 110 and for operating the CED 122. The position of the charger 110 may be adjustable for positioning the remote control device 118 to operate the CED 122. The charger 110 may be wireless for enhancing mobility, where the power supply for the charger 110 is a battery and the network communication means 314 is wireless, such as an RF transceiver coupled to a down-converter for converting the received signals to a digital format.

It will be understood that various modifications may be made to the embodiments disclosed herein and that the above description should not be construed as limiting, but merely as exemplifications of preferred embodiments. For example, the charger 110 may be in communication with an Internet-connected personal computer (PC) and receive data updates from the PC. Further, the remote control device 118 of the present disclosure may be designed to operate by using other type of signals besides RF signals, such as infrared signals. Accordingly, those skilled in the art will envision other modifications within the scope and spirit of the claims appended hereto.

What is claimed is:

1. A charger system comprising:
a charger comprising coupling means for coupling to a rechargeable device, wherein the coupling means includes charging means for providing an electrical charge to the rechargeable device and means for transferring data to the rechargeable device; and
means for receiving the data from a remote source and selectably transferring the data upon receipt to at least one of the means for transferring and a storage means of the charger.

2. The charger system of claim 1, wherein the charging means provides an electrical charge to the rechargeable device and the means for transferring transfers the data to the rechargeable device simultaneously.

3. The charger system of claim 1, wherein the means for receiving data receives the data from the remote source via the Internet.

4. The charger system of claim 1, wherein the rechargeable device is a device capable of functioning as a remote control device.

5. The charger system of claim 1, wherein the data includes a list of executable commands.

6. The charger system of claim 1, wherein the data includes a schedule for operating an electronic device via the rechargeable device.

7. A method for providing data to a rechargeable electronic device comprising the steps of:
receiving data from a remote source via a charging device;
selectably storing the received data within the charging device;
coupling the rechargeable electronic device to the charging device;
charging the rechargeable electronic device; and
selectably transferring the stored data and the received data from the charging device to the rechargeable electronic device.

8. The method of claim 7, wherein the remote source is a server; and further including the step of initiating transfer of the data from the server to the charging device by transmitting a request signal to the server.

9. The method of claim 7, further including the steps of:
processing the data transferred to the rechargeable electronic device; and
controlling an electronic device via the rechargeable electronic device in accordance with the processed data.

10. The method of claim 8, further including the step of programming the charging device via the remote source to transmit the request signal to the server.

11. The method of claim 8, further including the step of programming the charging device via the rechargeable electronic device to transmit the request signal to the server.

12. The method of claim 7, further including the step of notifying the remote source of the availability of the charging device for receiving the data.

13. The method of claim 7, further including the step of replacing previously stored data within the charging device with the data received from the remote source.

14. The method of claim 7, further including the steps of:
storing the data transferred from the charging device to the rechargeable electronic device within the rechargeable electronic device;
replacing previously stored data within the rechargeable electronic device with the data transferred from the charging device.

15. A charger system comprising:
means for receiving data from a remote source via a charging device;
means for selectably storing the received data within the charging device;
means for coupling the rechargeable electronic device to the charging device;
means for charging the rechargeable electronic device; and
means for selectably transferring the stored data and the received data from the charging device to the rechargeable electronic device.

16. The charger system of claim 15, further comprising:
means for processing the data transferred to the rechargeable electronic device; and
means for controlling an electronic device via the rechargeable electronic device in accordance with the processed data.

17. The method of claim 15, wherein the remote source is a server; and further comprising means for initiating transfer of the data from the server to the charging device by transmitting a request signal to the server.

18. The charger system of claim 17, further comprising means for programming the charging device via the remote source to transmit the request signal to the server.

19. The charger system of claim 17, further comprising means for programming the charging device via the rechargeable electronic device to transmit the request signal to the server.
